(19) United States
(12) Patent Application Publication
(10) Pub. No.: US 2020/0027832 A1
(43) Pub. Date: Jan. 23, 2020

(54) DEVICE STRUCTURE AND TECHNIQUES FOR FORMING SEMICONDUCTOR DEVICE HAVING ANGLED CONDUCTORS

(71) Applicant: Varian Semiconductor Equipment Associates, Inc., Gloucester, MA (US)

(72) Inventors: Sony Varghese, Manchester, MA (US); Anthony Renau, West Newbury, MA (US); Morgan Evans, Manchester, MA (US); John Hautala, Beverly, MA (US); Joe Olson, Beverly, MA (US); Min Gyu Sung, Essex, ME (US)

(73) Assignee: Varian Semiconductor Equipment Associates, Inc., Gloucester, MA (US)

(21) Appl. No.: 16/037,906

(22) Filed: Jul. 17, 2018

(51) Int. Cl. H01L 23/528; H01L 27/108; H01L 27/06; H01L 21/768

(52) U.S. Cl. CPC H01L 23/5283; H01L 27/10879; H01L 21/76877; H01L 27/1085; H01L 27/0688; H01L 27/10885

(57) ABSTRACT

A method of forming a device may include forming a component in a first level of a device structure; forming a contact cavity overlapping the component, the contact cavity forming a non-zero angle of inclination with respect to a perpendicular to a substrate plane. The method may further include filling the contact cavity with a conductor, wherein an angled conductor is formed, wherein the angled conductor extends to a second level of the device structure.

### FIELD

The present embodiments relate to semiconductor device structures, and more particularly, to structures and processing for memory devices including dynamic random access devices.

### BACKGROUND

As semiconductor devices, including logic devices and memory devices, such as dynamic random-access memory (DRAM) devices, scale to smaller dimensions, device patterning increasingly limits the ability to harness the improvements potentially resulting from smaller size. While many semiconductor devices are fabricated as three-dimensional structures, such as DRAM devices, fin-type field effect transistors (finFET), and other structures, fabricating such devices may involve the synthesis of different devices or components in a layer-by-layer fashion, often involving many sequential lithography operations. A given layer or level may define certain components arranged in planar fashion parallel to a surface of the substrate, meaning generally parallel to the flat face of a semiconductor wafer. Such device structures may be considered to be formed in many levels, where devices or components arranged in different levels may electrically communicate with one another through conductive structures arranged in vertical fashion, perpendicular to the substrate plane. As such, known device formation sequences entail layout of two different devices or components in different levels, where the first device is stacked vertically on top of a second device. Said differently, a first device arranged in a first level is arranged to overlap a second device in a second level in plan view, so a vertical connection may be formed between the two devices.

The above considerations place constraints upon device design in multi-level device structures, and in particular on so-called overlay issues. For example, an intervening component or device cannot be placed in an intervening level between a first level and second level, if the intervening component is positioned over the first component or under the second component, and blocks the vertical connection between the first device and second device. In present day DRAM devices, known architectures include so-called 8F² and 6F², among others. While 6F² architecture provides a higher device density and greater speed than 8F² architecture, the ability to form memory devices having appropriate properties is compromised, in part because of patterning problems, such as overlay.

With respect to these and other considerations, the present disclosure is provided.

### BRIEF SUMMARY

In one embodiment, a method of forming a device is provided. The method may include forming a component in a first level of a device structure, forming a contact cavity overlapping the component, the contact cavity forming a non-zero angle of inclination with respect to a perpendicular to a substrate plane. The method may include filling the contact cavity with a conductor, wherein an angled conductor is formed, wherein the angled conductor extends to a second level of the device structure.

In a further embodiment, a multi-level device may include a first component, disposed at least partially in a first level; a second component, disposed at least partially in a second level, above the first level, wherein the first level and the second level are parallel to a substrate plane. The multi-level device may further include an angled conductor, the angled conductor extending between the first component and the second component, and defining a non-zero angle of inclination with respect to a perpendicular to the substrate plane.

In another embodiment, a method of fabricating a multi-level semiconductor device may include forming an active device region in a first level of the semiconductor device. The method may include forming a set of conductor lines in an intermediate level of the semiconductor device, above the first level. The method may also include forming an angled conductor in contact with the active device region, the angled conductor forming a non-zero angle of inclination with respect to a perpendicular to a substrate plane of the semiconductor device, wherein the angled conductor does not contact the set of conductor lines. The method may further include forming an upper component in an upper level of the multi-level semiconductor device, above the intermediate level, wherein the angled conductor contacts the upper component.

### BRIEF DESCRIPTION OF THE DRAWINGS

FIG. 1A to FIG. 1G show a device structure at various stages of fabrication, according to some embodiments of the disclosure;

FIG. 1H depicts a variant of device structure of FIG. 1G;

FIG. 2A, FIG. 2B, and FIG. 2C depict components of an intermediate level of the device structure of FIG. 1G;

FIG. 3A shows a side view of an apparatus according to embodiments of the disclosure;

FIG. 3B shows a top plan view of a portion of the apparatus of FIG. 3A;

FIG. 3C shows an enlarged top plan view of showing details of the mask geometry of FIG. 3B; and

FIG. 4A and FIG. 4B show an exemplary structure, before and after etching, respectively, according to an embodiment of the disclosure; and

FIG. 5 shows an exemplary process flow in accordance with embodiments of the disclosure.

### DETAILED DESCRIPTION

The present embodiments will now be described more fully hereinafter with reference to the accompanying drawings, where some embodiments are shown. The subject matter of the present disclosure may be embodied in many different forms and are not to be construed as limited to the embodiments set forth herein. These embodiments are provided so this disclosure will be thorough and complete, and will fully convey the scope of the subject matter to those skilled in the art. In the drawings, like numbers refer to like elements throughout.

The present embodiments provide novel techniques and substrate structures to form devices, including logic devices and memory devices, formed in a semiconductor substrate. These techniques may especially be applicable to formation of DRAM devices, while other devices may also be formed according to the embodiments of the disclosure. These other devices may include NAND devices, including 3DNAND devices, NOR devices, X point memories and logic devices

In various embodiments novel techniques are provided to create electrical connections between semiconductor structures in semiconductor devices such as memory devices such as DRAM, NAND, 3DNAND, NOR, X point memories and Logic devices.

Various embodiments provide device structures and techniques employing angled conductor lines as well as angled trenches to enable new semiconductor architectures. Some embodiments provide structures to self-align vias at an angle relative to the surface of a substrate, such as a semiconductor wafer. These angled vias may increase contact area between structures disposed in different levels of a semiconductor device where the structures are not vertically aligned to one another vertically.

In particular embodiments, angled contacts are provided to link different devices or different components of semiconductor devices and circuits, where the different components are arranged in different levels of a multi-level device. In the embodiments to follow techniques and structures are provided where a contact cavity is formed to link a component on the first level of a multi-level device, to another component on another level of the multi-level device. A “component” may refer to a device, an active area of a device, such as a semiconductor region, a conductive structure, such as a conductive line, or other structure, such as a capacitor. The contact cavity of the present embodiments may be arranged at a non-zero angle of inclination with respect to a perpendicular to a substrate plane, meaning the contact cavity is not arranged in a vertical fashion between different levels. The contact cavity may then be filled with a conductor to form an angled conductor linking different components, disposed on different levels of the multi-level device. Because the angled conductor and therefore the contact cavity is disposed at a non-zero angle of incidence, the first end and second end of the angled conductor may be shifted from one another within the substrate plane, as opposed to vertical contact structures, where the first end and second end are mutually disposed over or under one another. In some examples, the first end and second end of the angled conductor may not overlap one another at all. As described below, in configurations of multi-level devices having at least three levels, this novel geometry provides distinct advantages over known device structures. According to some embodiments, described below, a plurality of different angled cavity structures may be formed in a device structure, where the different angled cavity structures are used to form different angled features, operating synergistically to provide improved arrangement of components within a multi-level device structure.

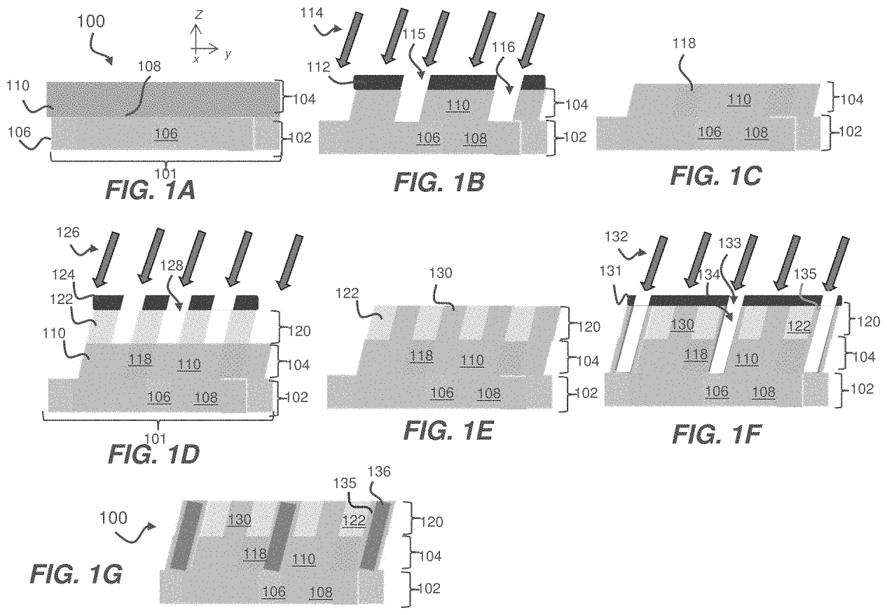

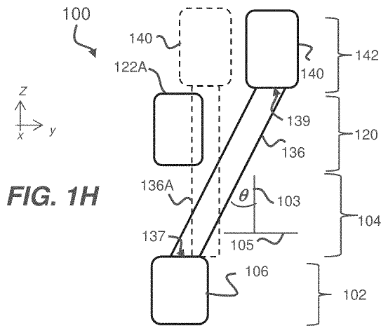

FIG. 1A to FIG. 1G show a device structure 100 arranged within a substrate 101, at various stages of fabrication, according to some embodiments of the disclosure. The substrate 101 may include other features (not shown), such as a subjacent substrate base, formed of a semiconductor material, such as silicon. The sequence shown begins at a stage of fabrication of a device at a first level 102, where the first level 102 includes a component, shown as an active region 106, and an insulator region 108, meaning an electrical insulator. The first level may be an isolation level, such as a so-called shallow trench isolation (STI) level, where the active region is monocrystalline semiconductor, such as silicon. The embodiments are not limited in this context. At the instance in FIG. 1A, an insulator layer 110 has been deposited, defining an adjacent level 104. The adjacent level 104 may be used to define various components or portions of components, including contacts.

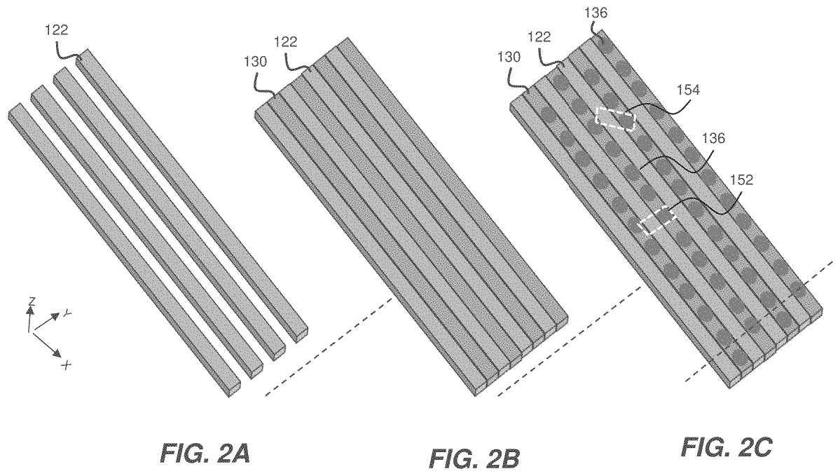

Turning to FIG. 1B, there is shown an instance after formation of a mask 112 on the insulator layer 110. The mask 112 is patterned in a manner to generate an array of openings 115. A given opening is used to form a contact via, as detailed below. According to various embodiments, the mask 112 may include a combination of at least one layer, such as known layers used for patterning, including, but not limited to, nitride, carbon, oxide, or resist. In various non-limiting embodiments, the thickness of the mask 112 may range from 10 nm to 100 nm. The mask 112 may be generally made of a different material than the insulator layer 110. The mask 112 may accordingly be used to transfer the pattern of the array of openings 115 into insulator layer 110. As further depicted in FIG. 2B, first angled ions 114 are directed to the substrate 101 in a first ion exposure at a non-zero angle of incidence (θ) with respect to a perpendicular 103 to a substrate plane 105. As such, the first angled ions 114 may etch the insulator layer 110, forming angled cavities 116. The first angled ions 114 may etch the insulator layer 110 (such as silicon oxide, silicon nitride) in a manner selective to the mask 112. For example, the first angled ions 114 may be provided in a reactive ion etching gas composition suitable to etch the insulator layer 110 at a higher etch rate than the etch rate of material of the mask 112. Such recipes are well known for various mask/insulator combinations, including carbon, oxide, nitride, metal(s), and will not be discussed further herein. In other examples where the mask 112 has sufficient thickness, such as a known hard mask material or a photoresist material, the etch rate of the insulator layer 110 need not be faster than the etch rate of the material of mask 112, to the extent the mask 112 is not completely eroded before completion of etching of the insulator layer 110. After formation of angled cavities 116, the angled cavities 116 may subsequently be filled with conductive material, forming conductive angled structures 118, shown in FIG. 1C. As an example, the conductive angled structures 118 may be formed of silicon or polysilicon in the adjacent level 104.

Subsequently to the instance of FIG. 1C, an additional layer and additional level of the device structure 100 may be formed, on top of the adjacent level 104. For example, in a device structure using conductive lines to interconnect various components, a metal layer may be deposited over the adjacent level 104. As an example, a blanket metal deposition may be performed using known techniques to form a blanket layer over the adjacent level 104. In embodiments of a DRAM device, the blanket layer may constitute a conductor level for forming wiring to cells of the DRAM device, such as a bitline level. In FIG. 1D, this conductor level is shown as intermediate level 120. Exemplary materials for use as a conductor in the intermediate level 120 may be any suitable metal material, such as tungsten (W), a layer structure, such as W/Ruthenium, and alloy, or other suitable metal. As shown in FIG. 1D, a mask 124 is deposited on the metal of the intermediate level 120, while second angled ions 126 are directed toward the substrate 101. The second angled ions 126 may, but need not, etch the metal of intermediate level 120 at a faster etch rate than an etch rate of the material of mask 124. As such, the second angled ions 126 may etch the metal layer throughout the thickness of the intermediate level 120, forming angled cavities 128, where the angled cavities also define angled conductor lines 122. In accordance with some embodiments, the angled conductor lines 122 may be positioned and angled in a manner to locate the bottom surfaces of the angled conductor lines 122 to contact designed components in the subjacent layer, such as angled conductive angled structures 118 in adjacent level 104.

In a subsequent operation, depicted at FIG. 1E, the intermediate level 120 may be filled with insulator 130 and polished, resulting in the structure shown, where insulator 130 is disposed between the angled conductor lines 122.

Turning now to FIG. 1F, a subsequent operation is depicted, where a mask 131 is deposited on the intermediate level 120. The mask 131 may be patterned in a manner where openings 133 in the mask 131 are aligned with the regions of insulator 130. As shown in FIG. 1F, third angled ions 132 are directed toward the substrate 101, and impact regions of insulator 130 in the intermediate level 120, as well as insulator layer 110 in adjacent level 104. The third angled ions 132 may, but need not, etch the material of the insulator 130 and insulator layer 110 faster than material of the mask 131. As such, the third angled ions 132 may etch insulator material throughout the thickness of the intermediate level 120, and the adjacent level 104, forming angled cavities 134, where the angled cavities 134 extend to the first level 102, and abut against the active region 106. As shown in FIG. 1F, a liner 135 may be formed in the angled cavities 134, where the liner 135 is made of an insulator material.

Turning to FIG. 1G there is shown a subsequent instance after the angled cavities 134 are filled with a suitable conductor, forming angled conductors 136. As shown, the angled conductors 136 extend through the adjacent level 104, and intermediate level 120 to contact the active region 106. While not shown explicitly in FIG. 1G, in various embodiments, the angled conductors 136 may abut against a component in a higher level, above the intermediate level 120. In FIG. 1H, the

Turning to FIG. 1H there is shown one variant of the device structure 100, after formation of a component 140, in an upper level 142, where the upper level 142 is disposed above the intermediate level 120. Various components discussed above are omitted for clarity. Shown in FIG. 1H are details of the geometry of the angled conductor 136. The angled conductor 136 may be arranged at a non-zero angle of inclination with respect to the perpendicular 103 to the substrate plane 105 (X-Y plane). In this variant, conductor lines 122A are disposed directly over the active regions 106. The conductor lines 122A need not be angled conductor lines, as described with respect to FIG. 1D. In this example, the device structure 100 represents a multi-level device, such as a multi-level semiconductor device, where a first component (active region 106) formed in a first level 102 is electrically connected to a second component (component 140) is a second level (upper level 142) using an angled conductor 136.

A salient feature of the geometry of FIG. 1H is where a third component (conductor lines 122A) is arranged above the first component (active region 106), while a given conductor line of conductor lines 122A is not in electrical contact with the active region 106, below. In other words, the angled conductor 136 establishes electrical contact between the active region 106 and component 140, in a higher level, while another component (conductor lines 122A) is disposed above the active region 106 and does not electrically contact the angled conductor 136.

In some embodiments, the active region 106 may be an active semiconductor region of a dynamic random-access memory (DRAM) cell, where the angled conductor lines 122 comprise a bitlines of the DRAM cell, and the component 140 comprises a storage capacitor.

As further shown in FIG. 1H, the angled conductor avoids incomplete overlap of the bottom surface of a conductor connecting the active region 106 to a component 140 in a higher level, when the conductor is arranged as a vertical conductor. Notably, when a component (conductor lines 122A) is disposed in an intermediate level between another component (active region 106) in a first level, and a further component (component 140) in a higher level, the use of a vertical conductor 136A may force shifting the position of the vertical conductor 136A to avoid the conductor lines 122A. This shifting (in the X-Y plane) results in an undesirable incomplete overlap between the bottom surface of the conductor and the active region 106.

While the embodiment of FIG. 1H illustrates an angled conductor where the bottom surface 137 is displaced with respect to the top surface 139 along a first direction (Y-axis) in the X-Y plane in other embodiments, in additional embodiments, the bottom surface and top surface of an angled conductor may be shifted from one another in the X- and Y direction. FIG. 2A, FIG. 2B, and FIG. 2C depict components of the intermediate level 120 to illustrate different configurations of an angled conductor. In FIG. 2A, the angled conductor lines 122 are shown extending along the X-axis in an array of lines within the X-Y plane. At FIG. 2B, the insulator 130 is shown, disposed between the angled conductor lines 122.

At FIG. 2C, a portion of the angled conductor 136 is shown in cross-section, where the angled conductor 136 is arranged in a two-dimensional array of angled conductors 136. In this example, the angled conductor 136 may represent an array of conductive vias, linking a first level and an upper level. In FIG. 2C, a projection 152 of an angled conductor 136 within the X-Y plane is shown, consistent with the geometry of FIG. 1H, where the angled conductor extends under the angled conductor lines 122 at the first level 102. In the variant of angled conductor 136 shown by projection 152, the angled conductor position of the angled conductor 136 does not change along the X-axis. In FIG. 2C, another projection, shown as projection 154 of the angled conductor 136 within the X-Y plane is shown, consistent with the geometry of FIG. 1H, where the angled conductor extends under the angled conductor lines 122 at the first level 102. In the variant of angled conductor 136 shown by projection 154, the angled conductor position of the angled conductor 136 does change along the X-axis.

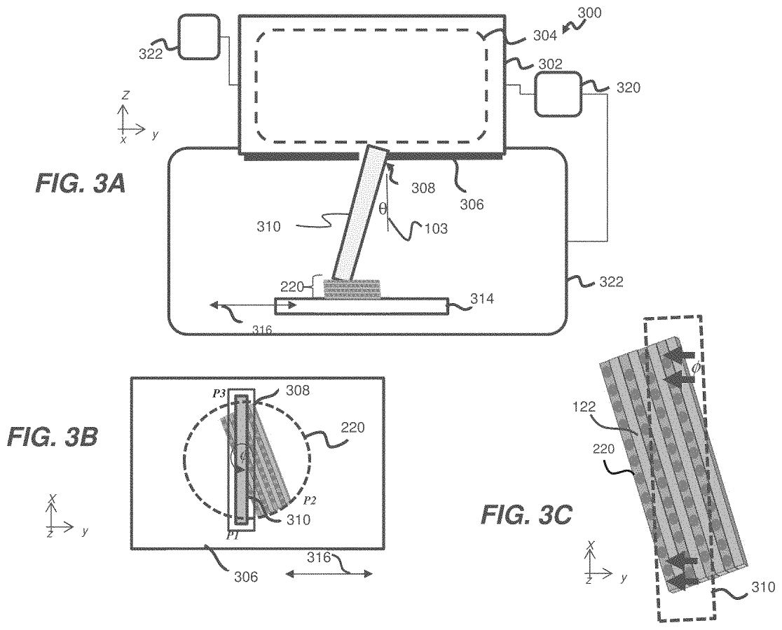

Turning now to FIG. 3A, there is shown a processing apparatus 300, depicted in schematic form. The processing apparatus 300 represents a processing apparatus for etching portions of a substrate, to form angled cavities, as generally described above. The processing apparatus 300 may be a plasma based processing system having a plasma chamber 302 for generating a plasma 304 therein by any convenient method as known in the art. An extraction plate 306 may be provided as shown, having an extraction aperture 308, where a selective etching may be performed to reactively etch an insulator layer with respect to a mask material. A substrate 220, including, for example, the aforementioned structure, device structure 100, is disposed in the process chamber 322. A substrate plane of the substrate 220 is represented by the X-Y plane of the Cartesian coordinate system shown, while the perpendicular 103 to the plane of the substrate 220 lies along the Z-axis (Z-direction).

The processing apparatus 300 may employed to generate angled structures by performing an angled reactive ion beam etching, where reactive species may be provided as part of an ion beam or in addition to the ion beam. During an angled reactive ion beam etching operation, an ion beam 310 is extracted through the extraction aperture 308. As shown in FIG. 3A, the ion beam 310 forms a non-zero angle of incidence with respect to the perpendicular 103, shown as θ. The trajectories of ions within the ion beam 310 may be mutually parallel to one another or may lie within a narrow angular range, such as within 10 degrees of one another or less. Thus, the value of θ may represent an average value of incidence angle where the individually trajectories vary up to several degrees from the average value. The ion beam 310 may be extracted when a voltage difference is applied using bias supply 320 between the plasma chamber 302 and substrate 220 as in known systems. The bias supply 320 may be coupled to the process chamber 322, for example, where the process chamber 322 and substrate 220 are held at the same potential. In various embodiments, the ion beam 310 may be extracted as a continuous beam or as a pulsed ion beam as in known systems. For example, the bias supply 320 may be configured to supply a voltage difference between plasma chamber 302 and process chamber 322, as a pulsed DC voltage, where the voltage, pulse frequency, and duty cycle of the pulsed voltage may be independently adjusted from one another.

In various embodiments, for example, the ion beam 310 may be provided as a ribbon ion beam having a long axis extending along the X-direction of the Cartesian coordinate system shown in FIG. 3B. As further shown in FIG. 3C, during the operation of FIG. 3A, the substrate 220 may be oriented in a manner where the long direction of the angled conductor lines 122 may be oriented at a desired twist angle θ with respect to the long axis of the extraction aperture 308. As shown by the arrows in FIG. 3C, the projection (in the X-Y plane) of trajectories of ions of the ion beam 310 align perpendicularly with respect to the long axis of the extraction aperture 308. Thus, in addition to defining the non-zero angle of incidence with respect to the perpendicular, shown as θ. In FIG. 3A, the ion beam 310 also defines a twist angle with respect to a substrate, or a set of structures within a substrate. Thus, when the angled conductor lines 122 are oriented with their long direction parallel to the long axis of the extraction aperture 308, the angled conductors 136 may be generated with the orientation as represented by the projection 152. When the long direction of the angled conductor lines 122 are oriented to define a non-zero twist angle, the angled conductors 136 may be generated with the orientation as represented by the projection 154.

By scanning a substrate stage 314 including substrate 220 with respect to the extraction aperture 308, and thus with respect to the ion beam 310 along the scan direction 316, the ion beam 310 may etch a set of angled cavities oriented at a non-zero angle of inclination with respect to the perpendicular 103, across different portions of the substrate 220. In this example of FIG. 3B, the substrate 220 is a circular wafer, such as a silicon wafer, the extraction aperture 308 is an elongated aperture, having an elongated shape. The ion beam 310 is provided as a ribbon ion beam extending to a beam width along the X-direction, where the beam width is adequate to expose an entire width of the substrate 101, even at the widest part along the X-direction. Exemplary beam widths may be in the range of 10 cm, 20 cm, 30 cm, or more while exemplary beam lengths along the Y-direction may be in the range of 3 mm, 5 mm, 10 mm, or 20 mm. The embodiments are not limited in this context.

According to the present embodiments, the ion beam 310 may be composed of any convenient gas mixture, including inert gas, reactive gas, and may be provided in conjunction with other gaseous species in some embodiments. In particular embodiments, the ion beam 310 and other reactive species may be provided as an etch recipe to the substrate 220 so as to perform a directed reactive ion etching of material within a given level of a device structure, such as device structure 100. Such an etch recipe may use known reactive ion etch chemistries for etching materials such as oxide, nitride, metal or other material, as known in the art. For a given etch operation, the reactive etch recipe may, but need not be, selective with respect to the material a mask. In accordance with embodiments of the disclosure, a series of different angled cavities may be etched in a series of different etch operations using the processing apparatus 300, where the geometry of the ion beam 310, as well as the chemistry of the plasma 304 may be adjusted as appropriate between the different etch operations.

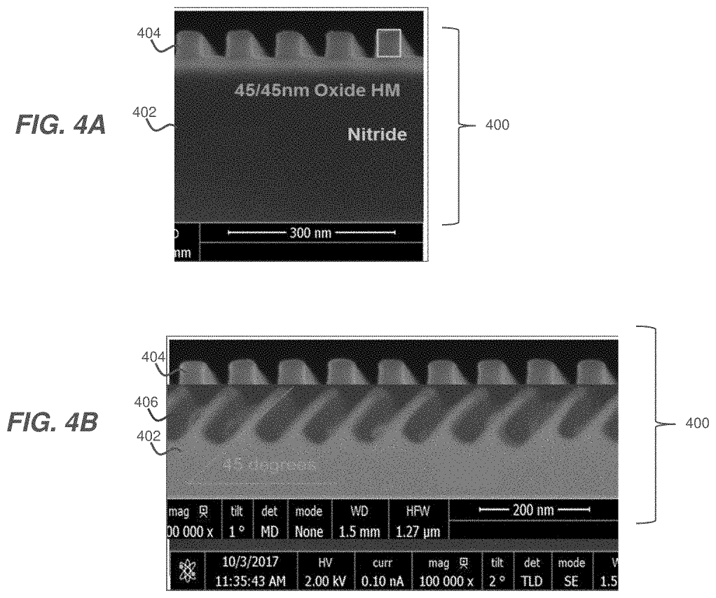

FIG. 4A and FIG. 4B depict exemplary results of angled reactive ion beam etching to form angled cavities using a processing apparatus arranged according to FIG. 3A. In FIG. 4A, a substrate 400 is provided, having a nitride layer 402, and an oxide mask 404, disposed on the nitride layer 402. The oxide mask 404 is formed from an array of 45 nm lines separated by 45 nm. A reactive ion beam etching process has been performed wherein an ion beam is directed at a 45-degree angle of incidence with respect to the perpendicular to the substrate plane, as described above. As shown in FIG. 4B, a series of angled cavities 406 are formed within the nitride layer 402, at an angle of inclination of 45 degrees.

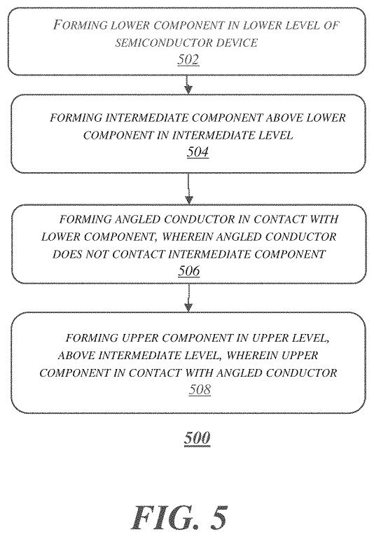

FIG. 5 depicts an exemplary process flow 500, according to embodiments of the disclosure. At block 502, a lower component is formed in a lower level of a semiconductor device. In some examples, the lower component may be an active device region, such as a semiconductor region.

At block 504, an intermediate component is formed above the lower component in an intermediate level.

At block 506, an angled conductor is formed in contact with the lower component, in a manner where the angled conductor does not contact the intermediate component in the intermediate level. In some embodiments, the angled conductor may be formed by reactive ion beam etching of a material. In some embodiments may be formed by etching material disposed in more than one level, to form an angled cavity, to be filled by any suitable conductive material.

At block 508, an upper component is formed in an upper level, above the intermediate level, where the upper component is in contact with the angled conductor. In this manner, a lower component in a lower level may be electrically connected to an upper component in an upper level, while avoiding contact with an intermediate component in an intermediate level, disposed between the lower level and the upper level.

The present embodiments provide various advantages over known device structures including logic devices, hybrid devices, and memory device such as DRAM devices. For one advantage, the use of angled conductors provides design flexibility for designing different levels of a multi-level device, since components to be connected in different levels need not be situated over one another. For another advantage, contact area between a conductor and components in different levels can be maximized, since use of an angled conductor allows two different components to be shifted from one another in the X-Y plane, while still completely overlapping the angled conductor.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are in the tended to fall within the scope of the present disclosure. Furthermore, the present disclosure has been described herein in the context of a particular implementation in a particular environment for a particular purpose, while those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method of forming a device, comprising:
forming a component in a first level of a device structure;
forming a contact cavity overlapping the component, the contact cavity forming a non-zero angle of inclination with respect to a perpendicular to a substrate plane; and
filling the contact cavity with a conductor, wherein an angled conductor is formed, wherein the angled conductor extends to a second level of the device structure.

2. The method of claim 1, wherein the angled conductor has a first end and a second end, wherein the first end is shifted from the second end within the substrate plane.

3. The method of claim 2, wherein the first end does not overlap with the second end.

4. The method of claim 1, wherein the forming the contact cavity comprises:
providing a plurality of layers above the component, the plurality of layers forming the second level, and a third level, disposed between the first level and the second level;
forming a mask on at least one layer of the plurality of layers; and
directing angled ions to the mask in a first ion exposure, wherein the angled ions selectively etch the at least one layer with respect to the mask.

5. The method of claim 4, wherein the first ion exposure comprises:
providing the substrate in a process chamber, adjacent a plasma chamber;
extracting an ion beam from the plasma chamber into the process chamber through an extraction aperture, wherein the ion beam defining a non-zero angle of incidence with respect to the substrate plane; and
performing at least one scan wherein the substrate is scanned with respect to the extraction aperture when the substrate is exposed to the ion beam.

6. The method of claim 4, wherein the first ion exposure comprises:
etching the plurality of layers above the component.

7. The method of claim 1, wherein the component comprises an active semiconductor region.

8. A multi-level device, comprising:
a first component, disposed at least partially in a first level;
a second component, disposed at least partially in a second level, above the first level, wherein the first level and the second level are parallel to a substrate plane; and
an angled conductor, the angled conductor extending between the first component and the second component, and defining a non-zero angle of inclination with respect to a perpendicular to the substrate plane.

9. The multi-level device of claim 8, further comprising a third component, disposed in a third level, wherein the third component is arranged above the first component, and is not in electrical contact with the first component.

10. The multi-level device of claim 8, wherein the first component comprises an active semiconductor region.

11. The multi-level device of claim 9, wherein the first component comprises an active semiconductor region of a dynamic random-access memory (DRAM) cell, wherein the third component comprises a bitline of the DRAM cell.

12. The multi-level device of claim 8, wherein the second component comprises a storage capacitor, wherein the storage capacitor forms incomplete overlap with the active semiconductor region within the substrate plane from a plan view perspective.

13. The multi-level device of claim 12, wherein the storage capacitor forms no overlap with the active semiconductor region within the substrate plane from a plan view perspective.

14. The multi-level device of claim 10, wherein the angled conductor comprises a bottom surface, wherein an entirety of the bottom surface overlaps with the active semiconductor region.

15. The multi-level device of claim 12, wherein the angled conductor comprises a top surface, wherein an entirety of the top surface overlaps with the storage capacitor.

16. A method of fabricating a multi-level semiconductor device, comprising:
forming an active device region in a first level of the semiconductor device;
forming a set of conductor lines in an intermediate level of the semiconductor device, above the first level;
forming an angled conductor in contact with the active device region, the angled conductor forming a non-zero angle of inclination with respect to a perpendicular to a substrate plane of the semiconductor device, wherein the angled conductor does not contact the set of conductor lines; and
forming an upper component in an upper level of the multi-level semiconductor device, above the intermediate level, wherein the angled conductor contacts the upper component.

17. The method of claim 16, wherein the forming the angled conductor comprises:
forming a contact cavity, extending from the first level to the upper level,
the contact cavity extending at the non-zero angle of inclination with respect to the perpendicular to the substrate plane; and
filling the contact cavity with a conductor.
